(19) United States
(12) Patent Application Publication
(10) Pub. No.: US 2024/0006129 A1
(43) Pub. Date: Jan. 4, 2024

(54) UV-ABSORBING TRANSPARENT PEROVSKITE

(71) Applicant: The Trustees of Princeton University, Princeton, NJ (US)

(72) Inventors: Tianran LIU, Princeton, NJ (US); Xiaoming ZHAO, Princeton, NJ (US); Lynn LOO, Princeton, NJ (US)

(73) Assignee: The Trustees of Princeton University, Princeton, NJ (US)

(21) Appl. No.: 18/031,405

(22) PCT Filed: Oct. 11, 2021
(86) PCT No.: PCT/US2021/054383

§ 371 Date: Apr. 12, 2023

Related U.S. Application Data
(60) Provisional application No. 63/090,423, filed on Oct. 12, 2020.

(51) Int. Cl. H01G 9/20; H01L 31/0392; H01L 31/0264

(52) U.S. Cl. CPC H01G 9/20; H01L 31/0264; H01L 31/03928

(57) ABSTRACT

Transparent UV-absorbing solar cells are promising for the applications of powering electrochromic windows that regulate the transmission of visible and near-infrared photons for natural lighting and heating purposes, respectively. Current technologies focus on using organic solar cells for the application due to their narrow excitonic absorption and tunable bandgaps. However, transparent organic solar cells have drawbacks including the stability issue and thickness-induced problems, such as low yield rate and limited power conversion efficiency. Disclosed herein is the co-deposition of two or more materials by thermal evaporation to make visibly transparent inorganic perovskite films. By tuning the halide compositions, the inorganic perovskite films show absorption range in UV and near-UV region, which is well-suited to the application. Its high conductivity and absorbance enable it to be around 400 nm thick for devices, which is critical to improve the yield rate and efficiency. The solar cells based on the inorganic perovskite active layers show higher power conversion efficiency and higher transparency than state-of-art UV absorbing solar cells. The disclosed approach is not limited to the exemplary embodiment employing inorganic perovskite, and can employ, e.g., inorganic, organic and hybrid perovskite.

### CROSS-REFERENCE TO RELATED APPLICATIONS

This application claims priority to U.S. Provisional Patent Application No. 63/090,423, filed Oct. 12, 2020, which is herein incorporated by reference in its entirety.

### STATEMENT REGARDING FEDERALLY SPONSORED RESEARCH OR DEVELOPMENT

This invention was made with government support under Grant Nos. CMMI-1824674 and DMR-1420541 awarded by the National Science Foundation. The government has certain rights in the invention.

### FIELD OF THE INVENTION

The present invention relates to photo-absorbing perovskite layers and devices that utilize such layers, including three-dimensional perovskites, double perovskites, and two-dimensional perovskites.

### BACKGROUND

Transparent photovoltaics can be integrated into surfaces of buildings and vehicles to provide point-of-use power without impacting aesthetics. Ultraviolet-absorbing TPVs have thus been proposed for low-power applications that prioritize aesthetics, such as sourcing power for internet-of-things sensors, heads-up displays, and electrochromic windows that regulate the transmission of visible and near-IR photons for natural lighting and heating purposes. Present technologies focus on using UV-absorbing material system, such as small-molecule organics, metal oxides, metal halides, and organic-inorganic hybrid perovskites, as the active layer for UV-absorbing transparent photovoltaics. However, there are some drawbacks for the use of them. For example, some of them exhibit very low power conversion efficiencies (<0.1%), some UV-absorbers have not yet demonstrated compatibility with transparent top electrode deposition, while others suffer aesthetic issues, such as high haze, low transparency or colorful tint, and no reported UV-harvesting solar cells thus far have shown long-term operational stability or large-area compatibility.

Thus, photo-absorbing layers that avoid these issues are useful and desirable.

### BRIEF SUMMARY

The present disclosure provides visibly transparent inorganic perovskite solar cells.

A first aspect of the present disclosure is directed towards a visibly transparent photo-absorbing layer, where the visibly transparent photo-absorbing layer comprising a three-dimensional halide perovskite (including organic, inorganic or hybrid), a double perovskite, a two-dimensional perovskite, or a combination thereof. The three-dimensional halide perovskite preferably has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof, X is F, Cl, Br, I, or a combination thereof. The double perovskite preferably has the formula A₂BCX₆, where A is Cs, methylammonium (MA), formamidinium (FA), or combination thereof, B is Cu, Ag, Hg, Au, or a combination thereof; C is Sb, Bi, or a combination thereof; and X is F, Cl, Br, I, or a combination thereof. The two-dimensional perovskite preferably has the formula A₂Bₙ₋₁MₙX₃ₙ₊₁, where A is Cs, RNH₃ (where R is an organic group, such as C₆H₅(CH₂)₂), or a combination thereof, B is R′NH₃ (where R′ is an organic group, such as CH₃); M is Pb, Sn, Ge, Bi, Sb, Cu, Au, Ag or a combination thereof, X is F, Cl, Br, I, or a combination thereof, n denotes that number of M-X sheets in each inorganic layer, and n is at least 2. Depending on the application, the substrate may be, e.g., glass or an electron transport layer or a hole transport layer or flexible plastic films. Advantageously, 0≤x≤3. The visibly transparent photo-absorbing layer should have an absorption cutoff ≤470 nm, and a crystallite size >10 nm, and they are deposited onto appropriate substrates via thermal evaporation.

Advantageously, the visibly transparent photo-absorbing layer may have the formula: (i) CsₐMA_{b}FA_{c}Pb_{d}Ge_{c}Sn_{f}FₓCl_{y}Br_{z}, where a+b+c=1, d+e+f=1, x+y+z=3, 0≤a, b, c, d, e, f≤1, 0≤x, y, z≤3; (ii) Cs₂AgBiCl_{x+2y+3z}Br_{6-x-2y-3z}, where 0≤x≤1, 0≤y≤1, 0≤z≤1; (iii) PEA₂PbₐSn₁₋ₐCl_{2x+2y}Br_{4-2x-2y}, where 0≤a≤1, 0≤x≤1 and 0≤y≤1, and PEA is phenylethylamine; or (iv) Cs₂PbₓSn_{y}I₂Cl₂, where x+y=1, 0≤x≤1 and 0≤y≤1.

A second aspect of the present disclosure is directed towards a perovskite solar cell that utilizes the above-disclosed visibly transparent photo-absorbing layer. In particular, the perovskite solar cell in the conventional structure comprises or consists of: (i) a transparent electrode; (ii) an electron transport layer above the transparent electrode; (iii) a visibly transparent photo-absorbing layer above the electron transport layer, the visibly transparent photo-absorbing layer comprising three-dimensional halide perovskites, double perovskites, two-dimensional perovskites or a combination thereof with an absorption cutoff ≤470 nm and a crystallite size >10 nm; (iv) a hole transport layer above the visibly transparent photo-absorbing layer; and (v) a second electrode above the hole transport layer. Or the perovskite solar cell in the inverted structure comprises or consists of: (i) a transparent electrode; (ii) a hole transport layer above the transparent electrode; (iii) a visibly transparent photo-absorbing layer above the hole transport layer, the visibly transparent photo-absorbing layer comprising a three-dimensional halide perovskite, double perovskite, two-dimensional perovskite or a combination thereof with an absorption cutoff ≤470 nm and a crystallite size >10 nm; (iv) an electron transport layer or a buffer layer above the visibly transparent photo-absorbing layer; and (v) a second electrode above the electron transport layer. These structures can generally be described as comprising or consisting of a photovoltaic composite layer between a transparent electrode and a second electrode, where the photovoltaic composite layer comprises or consists of a visibly transparent photo-absorbing layer between an electron transport layer and a hole transport layer;

Advantageously, the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof.

Advantageously, the double perovskite has the formula A₂BCX₆, where A is Cs, methylammonium (MA), formamidinium (FA), or combination thereof, B is Cu, Ag, Hg, Au, or a combination thereof; C is Sb, Bi, or a combination thereof; and X is F, Cl, Br, I, or a combination thereof.

Advantageously, the two-dimensional perovskite has the formula A₂Bₙ₋₁MₙX₃ₙ₊₁, where A is Cs, RNH₃ (R is an organic group, such as C₆H₅(CH₂)₂) or a combination thereof, B is R′NH₃ (R′ is an organic group, such as CH₃); M is Pb, Sn, Ge, Bi, Sb, Cu, Au, Ag or a combination thereof, X is F, Cl, Br, I, or a combination thereof n denotes that number of M-X sheets in each inorganic layer.

Advantageously, the transparent electrode is indium tin oxide (ITO), fluorine doped tin oxide (FTO), indium zinc oxide, InZnAlO, ZnAlO, cadmium oxide, zirconium indium oxide, gallium zinc oxide, graphene, graphene oxide, a conductive nanotube, a conductive nanoparticle, graphite, carbon nanotube, carbon, Ag, Al, Au, Mo, Cu, Ni, Ca, Li, poly(3,4-ethylenedioxythiophene) polystyrene sulfonate (PEDOT:PSS) or a combination thereof and/or the electron transport layer is an oxide of a post-transition metal (such as TiO₂ or SnO₂), ZnO, ZnSnO₄, Cs₂CO₃, BaTiO₃, SrTiO₃, MgTiO₃, BaSnO₃, CdS, ZnTiO₃, WO₃, a conductive nanotube, a conductive nanoparticle, fullerene and its derivatives, self-assembled monolayers, MXene (2D transition metal carbides and nitrides with a composition of Mₙ₊₁XₙTₓ), indium gallium zinc oxide (InGaZnO₄), gallium nitride (GaN), niobium pentoxide (Nb₂O₅), In₂S₃, SnS₂, Bi₂S₃, MoS₂, WS₂, reduced graphene oxide, perylene diimide and its derivatives, naphthalene diimide and its derivatives, azaacene and its derivatives, n-type conjugated polymers, bathocuproine, bathophenanthroline, 2,2′,2″-(1,3,5-Benzinetriyl)-tris(1-phenyl-1-H-benzimidazole) (TPBi), tris[2,4,6-trimethyl-3-(pyridine-3-yl)phenyl]borane (3TPYMB), 3,3′,5,5′-tetra[(m-pyridyl)-phen-3-yl]biphenyl (BP4mPy), Tris(8-hydroxyquinoline)aluminum(III) (Alq₃), N,N′-Bis(naphthalen-1-yl)-N,N′-bis(phenyl)benzidine (NPD), 4,4′-Bis(N-carbazolyl)-1,1′-biphenyl (CBP), N,N′-Bis(3-methylphenyl)-N,N′-diphenylbenzidine (TPD), Tris(4-carbazoyl-9-ylphenyl)amine (TCTA), 1,1-Bis[(di-4-tolylamino)phenyl]cyclohexane (TAPC), 1,3,5-Tris(3-pyridyl-3-phenyl)benzene (TmPyPB), Hexaazatriphenylenehexacarbonitrile (HATCN), a derivative thereof, or a doped layer thereof, or a combination thereof and/or the hole transport layer comprises 2,2′,7,7′-tetrakis(N,N-di-p-methoxyphenyl-amine)-9,9′-spirobifluorene (spiro-OMeTAD), Pedot:PSS, Poly(3-hexylthiophene-2,5-diyl) (P3HT), Poly(triaryl amine) (PTAA), NiOₓ, CuSCN, Cu₂O, CuOₓ, CuO, MoOₓ, NiPc, CuPc, VOₓ, V₂Oₓ, Cr, CrOx, Co₃O₄, CoOₓ, Co_{1-y}Cu_{y}Oₓ, reduced graphene oxide, Alq₃, NPD, CBP, TPD, TCTA, TAPC, BP4mPy, TmPyPB, HATCN, Poly [(9,9-bis(3′-(N,N-dimethylamino)propyl)-2,7-fluorene)-alt-2,7-(9,9-dioctylfluorene)] (PFN), self-assembled monolayers, a conductive nanoparticle, a conductive nanotube, p-type conjugated polymers, a derivative thereof, or a doped layer thereof, or a combination thereof and/or the visibly transparent photo-absorbing layer is formed by via thermal co-evaporation, sequential thermal evaporation or a combination thereof of, using precursors that independently have compositions according to RXₙ, where X is F, Cl, Br, or I, n is 1-3 (depending on the valence of R), where R can be methylammonium (MA), formamidinium (FA), ethanediammonium, iso-propylammonium, dimethylammonium, guanidinium, piperidinium, pyridinium, pyrrolidinium, imidazolium, t-butylammonium, ANH₃ (A is an organic group, such as C₆H₅(CH₂)₂), a metal, such as Cs, Na, K, Rb, Ag, Au, Ba, Bi, Ca, Co, Cu, Er, Eu, Fe, Ga, Ge, Ho, Hg, In, La, Mg, Mn, Ni, Pb, Sb, Sm, Sn, Sr, Tb, Ti, Y, Yb, or Zn and/or the visibly transparent photo-absorbing layer is formed by thermal co-evaporation of several precursors onto an electron transport layer or a hole transport layer.

A third aspect of the present disclosure is drawn to a window that utilizes the above-disclosed visibly transparent photo-absorbing layer. In particular, disclosed is a window comprising or consisting of at least one glass substrate or flexible plastic (polymer) substrates having an inner surface and an outer surface, and at least one film in contact with the inner surface, the outer surface, or both. Each film comprises a visibly transparent photo-absorbing layer, the visibly transparent photo-absorbing layer comprising a three-dimensional halide perovskite, double perovskites, two-dimensional perovskites or a combination thereof, having an absorption cutoff ≤470 nm and a crystallite size >10 nm.

Advantageously, the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof.

Advantageously, the double perovskite has the formula A₂BCX₆, where A is Cs, methylammonium (MA), formamidinium (FA), or combination thereof, B is Cu, Ag, Hg, Au, or a combination thereof; C is Sb, Bi, or a combination thereof; and X is F, Cl, Br, I, or a combination thereof.

Advantageously, the two-dimensional perovskite has the formula A₂Bₙ₋₁MₙX₃ₙ₊₁, where A is Cs, RNH₃ (R is an organic group) or a combination thereof, B is R′NH₃ (R′ is an organic group); M is Pb, Sn, Ge, Bi, Sb, Cu, Au, Ag or a combination thereof, X is F, Cl, Br, I, or a combination thereof. n denotes that number of M-X sheets in each inorganic layer.

In some variations, the film on the window forms a perovskite solar cell in a conventional structure, comprising: (i) a transparent electrode; (ii) an electron transport layer above the transparent electrode; (iii) the visibly transparent photo-absorbing layer above the electron transport layer; (iv) a hole transport layer above the visibly transparent photo-absorbing layer; and (v) a second electrode above the hole transport layer; Or an inverted structure, comprising: (i) a transparent electrode; (ii) a hole transport layer above the transparent electrode; (iii) a visibly transparent photo-absorbing layer above the hole transport layer, the visibly transparent photo-absorbing layer above the electron transport layer; (iv) an electron transport layer or a buffer layer above the visibly transparent photo-absorbing layer; and (v) a second electrode above the electron transport layer. In such variations, the window preferably further comprises one or more electrochromic thin films in electrical communication with the perovskite solar cell.

A fourth aspect of the present disclosure is drawn to a method for manufacturing a device, such as a perovskite solar cell, that contains one of the disclosed photo-absorbing layers. The method generally requires providing a target substrate, such as an electron transport layer or a hole transport layer, and then forming a visibly transparent photo-absorbing layer comprising three-dimensional halide perovskite, double perovskites, two-dimensional perovskites or a combination thereof, via thermal coevaporation, sequential thermal evaporation or a combination thereof, having an absorption cutoff ≤470 nm, and a crystallite size >10 nm.

Advantageously, the method comprises selecting a number of precursors, compositions of each precursor, and determining a molar ratio of the precursors to achieve a desired perovskite composition

In some embodiments, the inorganic, organic, or hybrid perovskite is CsPbClₓBr₍₃₋ₓ₎, where 0≤x≤3, and wherein the inorganic, organic, or hybrid perovskite is formed by thermally co-evaporating CsCl, CsBr, and PbCl₂ onto the target substrate.

Advantageously, the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof.

Advantageously, the double perovskite has the formula A₂BCX₆, where A is Cs, methylammonium (MA), formamidinium (FA), or combination thereof, B is Cu, Ag, Hg, Au, or a combination thereof; C is Sb, Bi, or a combination thereof; and X is F, Cl, Br, I, or a combination thereof.

Advantageously, the two-dimensional perovskite has the formula A₂Bₙ₋₁MₙX₃ₙ₊₁, where A is Cs, RNH₃ (R is an organic group) or a combination thereof, B is R′NH₃ (R′ is an organic group); M is Pb, Sn, Ge, Bi, Sb, Cu, Au, Ag or a combination thereof, X is F, Cl, Br, I, or a combination thereof. n denotes that number of M-X sheets in each inorganic layer.

### BRIEF DESCRIPTION OF THE DRAWINGS

FIG. 1 is a graph of the absorbance of a 400 nm-thick film of CsPbCl₃ and CsPbCl_{2.5}Br_{0.5} and CsPbCl₂Br deposited on glass.

FIGS. 2A and 2B are schematic diagrams of embodiments of devices using the disclosed perovskite material.

FIGS. 3A, 3B, and 3C are schematic diagrams of embodiments of a window film using the disclosed perovskite material.

FIG. 4 is a schematic diagram of an embodiment of a tandem solar cell using the disclosed perovskite material.

FIG. 5A is a graph showing the transmission and photopic response profiles of a solar cell stack, the stack comprising Glass/ITO/SnO₂/Perovskite/Spiro/ITO.

FIG. 5B is a graph showing the Color coordinates of the solar cell stack from FIG. 5A (502) and AM 1.5G (501) on the CIE 1931 chromaticity diagram.

FIGS. 6A and 6B are graphs showing the performance of transparent solar cells. FIG. 6A is a graph of a current density-voltage characteristic of an embodiment of a transparent solar cell. FIG. 6B is a graph showing the external quantum efficiency (EQE) of an embodiment of a transparent solar cell.

FIG. 7 is a graph showing the operational stability of transparent solar cells under over 1000 hours' continuous simulated one-sun illumination.

FIG. 8A is a graph showing the J-V characteristics of a 1.2 cm² transparent device.

FIG. 8B is a graph showing photocurrent-area dependence of transparent devices having areas between 0.09 cm² and 25 cm².

### DETAILED DESCRIPTION

As used herein, the term “visibly transparent” refers to a property of average visible transparency (AVT) in the visible light range (e.g., 400 nm-700 nm) of at least 50%, preferably of at least 70% and more preferably still of at least 80%, and even more preferably still of at least 90%, and most preferably at least 95%. The AVT is calculated using

$$A V T = \frac{\int T ( λ ) P ( λ ) S ( λ ) d ( λ )}{\int P ( λ ) S ( λ ) d ( λ )}$$

where A is the wavelength, T is the transmission, P is the normalized photopic spectral response of the eye, and S is the solar irradiance.

Disclosed herein is a visibly transparent photo-absorbing perovskite comprising a type of perovskite selected from a three-dimensional halide perovskite, a double perovskite, one or more (preferably two or more) two-dimensional perovskites, or a combination thereof. The visibly transparent photo-absorbing perovskite is generally capable of absorbing at least one UV wavelength of light. This is generally at least one wavelength between 100 nm and 400 nm, and preferably at least one wavelength in the UVA/UVB range (280 nm to 400 nm) and more preferably at least one wavelength in the UVA range (315 nm to 400 nm).

In some preferred embodiments, the visibly transparent photo-absorbing perovskite is a three-dimensional metal halide perovskite. In such embodiments, the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof, X is F, Cl, Br, I, or a combination thereof.

In other embodiments, the visibly transparent photo-absorbing perovskite is a double perovskite. In such embodiments, the double perovskite preferably has the formula A₂BCX₆, where A is Cs, methylammonium (MA), formamidinium (FA), or combination thereof, B is Cu, Ag, Hg, Au, or a combination thereof, C is Sb, Bi, or a combination thereof, and X is F, Cl, Br, I, or a combination thereof.

In other embodiments, the visibly transparent photo-absorbing perovskite is a two-dimensional perovskite. In such embodiments, the two-dimensional perovskite has the formula A₂Bₙ₋₁MₙX₃ₙ₊₁, where A is Cs, RNH₃ (R is an organic group) or a combination thereof, B is R′NH₃ (R′ is an organic group); M is Pb, Sn, Ge, Bi, Sb, Cu, Au, Ag or a combination thereof; X is F, Cl, Br, I, or a combination thereof. n denotes that number of M-X sheets in each inorganic layer. In some embodiments, n is at least 2. In some embodiments where a plurality of two-dimensional perovskites are present, each perovskite will vary in n. In some embodiments, the plurality of two-dimensional perovskites comprises a first 2D-perovskite and second 2D-perovskite, and the first 2D-perovskite has a different value of n than the second 2D-perovskite. The organic groups, R and R′, in embodiments where A is RNH₃ or R′NH₃, may be any organic group, including an alkyl, alkenyl, alkynyl, or aryl groups. R and R′ are preferably different organic groups. In some embodiments, the organic group is a hydrocarbon, having between 1 and 10 carbons. For example, in some embodiments, R and R′ are independently C₆H₅(CH₂)₂ and CH₃.

In some preferred embodiments, the visible transparent photo-absorbing perovskite has the formula: (i) CsₐMA_{b}FA_{c}Pb_{d}Ge_{c}Sn_{f}FₓCl_{y}Br_{z}, where a+b+c=1, d+e+f=1, x+y+z=3, 0≤a, b, c, d, e, f≤1, 0≤x, y, z≤3; (ii) Cs₂AgBiCl_{x+2y+3z}Br_{6-x-2y-3z}, where 0≤x≤1, 0≤y≤1, 0≤z≤1; (iii) PEA₂PbₐSn₁₋ₐCl_{2x+2y}Br_{4-2x-2y}, where 0≤a≤1, 0≤x≤1 and 0≤y≤1; or (iv) Cs₂PbₓSn_{y}I₂Cl₂, where x+y=1, 0≤x≤1 and 0≤y≤1.

The disclosed perovskite layer preferably has an average absorbance A (where A=−log₁₀(T), T being the transmittance) across the visible light range less than or equal to 0.3, preferably less than or equal to 0.15, and more preferably less than or equal to 0.1, and even more preferably still less than or equal to 0.05, and most preferably less than or equal to 0.025.

These layers should have an absorption cutoff ≤470 nm. As used herein, the term “absorption cutoff” refers to the wavelength at which 1% transmission is observed (e.g., an absorbance of 2), above which the absorbance drops sharply towards zero, where it remains at or near zero for the remainder of the visible light range. In some embodiments, the layers have an absorption cutoff ≤468 nm, ≤466 nm, ≤464 nm, ≤462 nm, ≤460 nm, ≤458 nm, ≤456 nm, ≤454 nm, ≤452 nm, and/or ≤450 nm. In some embodiments, the absorption cutoff is also ≥400 nm, ≥405 nm, ≥410 nm, ≥415 nm, ≥420 nm, ≥425 nm, ≥430 nm, ≥435 nm, and/or ≥440 nm.

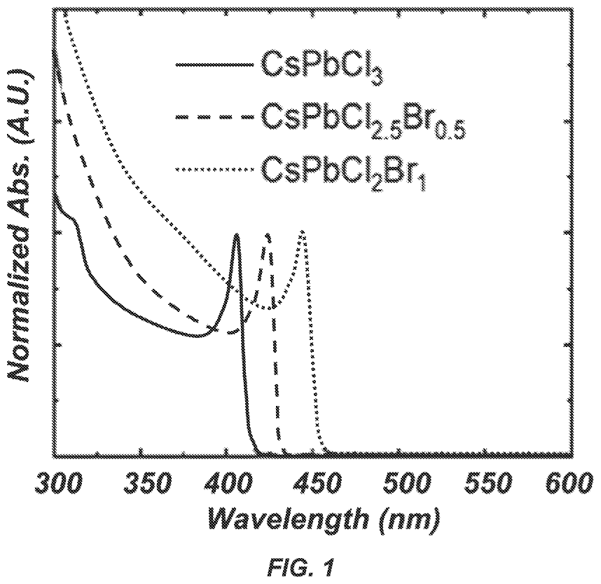

An example of this can be seen in FIG. 1, which provides absorbance measurements for three different perovskite layers. Each perovskite layer is 400 nm thick, on a quartz substrate. The first is CsPbCl₃, the second is CsPbCl_{2.5}Br_{0.5}, and the third is CsPbCl₂Br. As is seen, the absorbance curves are relatively similar in shape, but the absorbance cutoff shifts to the right as Br levels increase. In particular, FIG. 1 shows an absorbance cutoff (of around 415 nm for CsPbCl₃, around 435 nm for CsPbCl_{2.5}Br_{0.5}, and around 455 nm for CsPbCl₂Br. After those quickly dropping to near zero (e.g., CsPbCl₂Br shows absorbances of less than 0.1 after 455 nm), and throughout the rest of the visible range (note that while the graph in FIG. 1 stops at 600 nm, the absorption curves are flat throughout the remainder of the visible light wavelengths).

As can be seen, the introduction of Br causes the absorption cutoff to shift to the right (i.e., to shift to higher wavelengths) while also allowing for greater absorption in the UV wavelengths, and the UVA/UVB wavelengths (280-400 nm) in particular. Thus, UV absorbance can be tuned by adjusting the composition, with some visible transmission tradeoffs.

Each layer may be manufactured in any desired thickness. However, in some embodiments, these layers have a thickness t, where t<1 μm, and preferably t<500 nm, and where t>1 nm, and preferably t>100 nm.

The layer will have a crystallite size >10 nm. In some embodiments, the crystallite size is >20 nm, >30 nm, >40 nm, >50 nm, >60 nm, >70 nm, >80 nm, >90 nm, >100 nm, >200 nm, >300 nm, >400 nm, >500 nm, and/or >1 μm. The crystallite size can be determined using known techniques, such as using XRD and the Debye-Scherrer equation.

In some embodiments, a single type of perovskite is formed. In some embodiments, two different types of perovskites are formed. For example, in some embodiments, a three-dimensional perovskite is deposited, and then a two-dimensional perovskite is deposited over the three-dimensional perovskite, or the reverse (three-dimensional perovskite deposited over a two-dimensional perovskite).

While different types of perovskites will inherently have different compositions, In some embodiments, two perovskites are formed of the same type, but with different compositions. For example, in some embodiments, a first three-dimensional perovskite is formed with a first composition, and a second three-dimensional perovskite is formed with a second composition over the first perovskite.

The perovskite layer is typically deposited on a substrate. The substrate can be any appropriate substrate for deposition. For example, in some embodiments, the substrate is glass (e.g., borosilicate glass, alkali-aluminosilicate glass, etc.), while in other embodiments, the substrate is an electron transport layer (e.g., graphene/ZnO nanocomposite layers, TiO₂, SnO₂, etc.). In some embodiments, the substrate is another layer of a perovskite device (e.g., a perovskite solar cell) such as a hole transport layer.

When simply deposited on a substrate, the perovskite layer can serve as a UV-protective coating.

When the perovskite layer is used in a device, the device may be a stacked, layered device comprising a plurality of layers, such as, e.g., a perovskite solar cell.

A perovskite solar cell will generally comprise or consist of five, six, seven, or eight layers. The solar cell will generally include a first electrode. On top of that is a perovskite layer sandwiched between an electron transport layer (ETL) and a hole transport layer (HTL) (either the ETL or HTL may be the next layer after the first electrode), with a second electrode on top of the sandwiched layers. An optional substrate layer, or additional layers such as buffer layers, may also be incorporated.

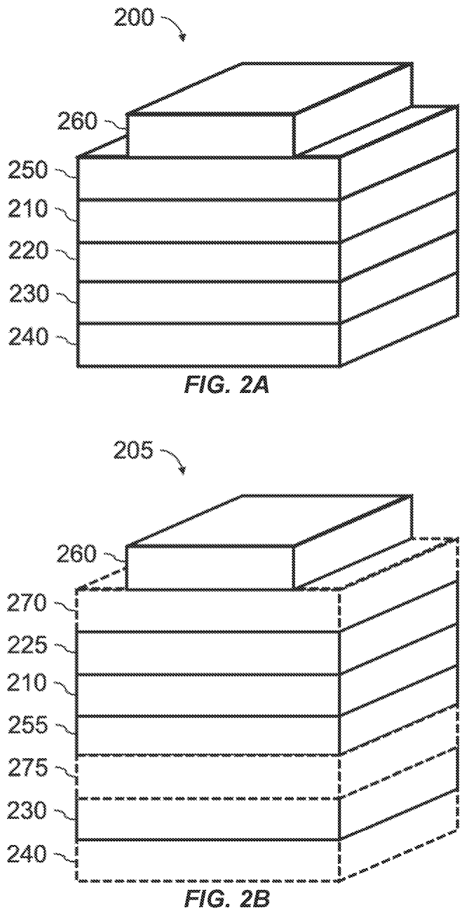

For example, referring to FIG. 2A, one embodiment of a perovskite solar cell (200) can be seen.

The first layer of the perovskite solar cell is a first electrode (230), typically a transparent electrode. In some embodiments, the transparent electrode may be, e.g., indium tin oxide (ITO), fluorine doped tin oxide (FTO), indium zinc oxide, InZnAlO, ZnAlO, cadmium oxide, zirconium indium oxide, gallium zinc oxide, graphene, graphene oxide, graphite, a conductive nanotube, a conductive nanoparticle, carbon nanotube, carbon, Ag, Al, Au, Mo, Cu, Ni, Ca, Li, poly(3,4-ethylenedioxythiophene) polystyrene sulfonate (PEDOT:PSS) or a combination thereof.

The first layer may exist on an optional layer, e.g., a substrate layer (240) such as a glass substrate or a flexible substrate. As discussed previously, the glass substrate may be any appropriate glass substrate, including, e.g., borosilicate glass, alkali-aluminosilicate glass, etc. The flexible substrate may be any appropriate flexible substrate, including, e.g., poly(ethylene 2,6-naphthalate (PEN), polyethylene terephthalate (PET), etc.

The second layer of the perovskite solar cell is an electron transport layer (ETL) (230) which is present above the first electrode/transparent electrode (240). In some embodiments, the ETL consists of or comprises an oxide of a post-transition metal (such as TiO₂ or SnO₂), ZnO, ZnSnO₄, Cs₂CO₃, BaTiO₃, SrTiO₃, MgTiO₃, BaSnO₃, CdS, ZnTiO₃, WO₃, fullerene and its derivatives, self-assembled monolayers, MXene (2D transition metal carbides and nitrides with a composition of Mₙ₊₁XₙTₓ), indium gallium zinc oxide (InGaZnO₄), gallium nitride (GaN), niobium pentoxide (Nb₂O₅), In₂S₃, SnS₂, Bi₂S₃, MoS₂, WS₂, reduced graphene oxide, perylene diimide and its derivatives, naphthalene diimide and its derivatives, azaacene and its derivatives, n-type conjugated polymers, bathocuproine, bathophenanthroline, 2,2′,2″-(1,3,5-Benzinetriyl)-tris(1-phenyl-1-H-benzimidazole) (TPBi), tris[2,4,6-trimethyl-3-(pyridine-3-yl)phenyl]borane (3TPYMB), 3,3′,5,5′-tetra[(m-pyridyl)-phen-3-yl]biphenyl (BP4mPy), Tris(8-hydroxyquinoline)aluminum(III) (Alq₃), N,N′-Bis(naphthalen-1-yl)-N,N′-bis(phenyl)benzidine (NPD), 4,4′-Bis(N-carbazolyl)-1,1′-biphenyl (CBP), N,N′-Bis(3-methylphenyl)-N,N′-diphenylbenzidine (TPD), Tris(4-carbazoyl-9-ylphenyl)amine (TCTA), 1,1-Bis[(di-4-tolylamino)phenyl]cyclohexane (TAPC), 1,3,5-Tris(3-pyridyl-3-phenyl)benzene (TmPyPB), Hexaazatriphenylenehexacarbonitrile (HATCN), a derivative thereof, or a doped layer thereof, or a combination thereof.

The third layer of the perovskite solar cell is the disclosed visibly transparent photo-absorbing layer (210) above and in contact with the electron transport layer (230). As discussed previously, the visibly transparent photo-absorbing layer comprises a three-dimensional halide perovskite, double perovskite, two-dimensional perovskite or a combination thereof. As discussed previously, the perovskite layer should have an absorption cutoff ≤470 nm, and a crystallite size >10 nm.

The perovskite layer should be formed via thermal evaporation. Thermal evaporation can be used to grow perovskite films from one or more sources, e.g., via either sequential evaporation of precursors, and/or by co-evaporation, where the precursors are evaporated at the same time.

For example, in one particular embodiment, the visibly transparent photo-absorbing layer is formed by thermal co-evaporation of CsCl, CsBr, and PbCl₂ onto an electron transport layer or a hole transport layer. The choice of precursors will be understood by those of skill in the art, based on the desired perovskite composition.

Generally, the precursors will comprise a plurality of halides, including at least one metal halide. For example, in some embodiments, all of the precursors, independently, have compositions according to RXₙ, where X is F, Cl, Br, or I, n is 1-3 (depending on the valence of R), where R can be Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, ANH₃ (A is an organic group), or a metal, such as Cs, Na, K, Rb, Ag, Au, Ba, Bi, Ca, Co, Cu, Er, Eu, Fe, Ga, Ge, Ho, Hg, In, La, Mg, Mn, Ni, Pb, Sb, Sm, Sn, Sr, Tb, Ti, Y, Yb, or Zn. The organic group, A, in ANH₃ precursors, may be any organic group, including an alkyl, alkenyl, alkynyl, or aryl groups. In some embodiments, the organic group is a hydrocarbon, having between 1 and 10 carbons. For example, in some embodiments, A is CH₃. In a preferred embodiment, A is C₆H₅(CH₂)₂.

In some embodiments, the perovskite layer has a thickness of between 200 nm and 800 nm.

The fourth layer of the perovskite solar cell is a hole transport layer (250) above and in contact with the visibly transparent photo-absorbing layer (210). The hole transport layer can be comprised of any material capable of functioning as hole transport layer. In some embodiments, the hole transport layer comprises a spiro-linked compound, such as 2,2′,7,7′-tetrakis(N,N-di-p-methoxyphenyl-amine)-9,9′-spirobifluorene (spiro-OMeTAD). In some embodiments, the hole transport layer is PEDOT:PSS Pedot:PSS, Poly(3-hexylthiophene-2,5-diyl) (P3HT), Poly(triaryl amine) (PTAA), NiOₓ, CuSCN, Cu₂O, CuOₓ, CuO, MoOₓ, NiPc, CuPc, VOₓ, V₂Oₓ, Cr, CrOₓ, Co₃O₄, CoOₓ, Co_{1-y}Cu_{y}Oₓ, reduced graphene oxide, Alq₃, NPD, CBP, TPD, TCTA, TAPC, BP4mPy, TmPyPB, HATCN, Poly [(9,9-bis(3′-(N,N-dimethylamino)propyl)-2,7-fluorene)-alt-2,7-(9,9-dioctylfluorene)] (PFN), self-assembled monolayers, a spiro-linked compound (such as 2,2′,7,7′-tetrakis(N,N-di-p-methoxyphenyl-amine)-9,9′-spirobifluorene (spiro-OMeTAD)), p-type conjugated polymers, a derivative thereof, or a doped layer thereof, or a combination thereof.

The fifth layer is a second electrode (260) above the hole transport layer (250). The second electrode may be comprised of any appropriate material for a second electrode, including, e.g., gold, aluminum, etc. The second electrode (260) may be a transparent electrode (e.g., comprising ITO, FTO, etc.), and may be the same or different from the first electrode (230).

An alternate embodiment of a perovskite solar cell is seen in FIG. 2B. There, the solar cell (205) is in an inverted arrangement, where the first electrode (230) is atop an optional substrate (240). A hole transport layer (255) is above the first electrode. A visibly transparent photo-absorbing layer (210) is above and in contact with the hole transport layer. An electron transport layer (225) is above and in contact with the visibly transparent photo-absorbing layer. And a second electrode (260) is above the electron transport layer.

Other layers known in the art may also be incorporated as well. In some embodiments, as seen in FIG. 2B, a device may include one or more buffer layers (270, 275), which may be introduced between the ETL and/or HTL and the corresponding electrode. In some embodiments, the buffer layer may comprise reduced graphene oxide, Cr, BP4mPy, TmPyPB, bathocuproine, or bathophenanthroline. Such additional layers may also readily be incorporated into other embodiments of solar cells, including the embodiments described with respect to FIG. 2A.

Due to the visible transparency of the composition of matter (and the whole solar cell/photovoltaic device, it can be applied to power various systems where transparency is desirable, including, e.g., smart windows.

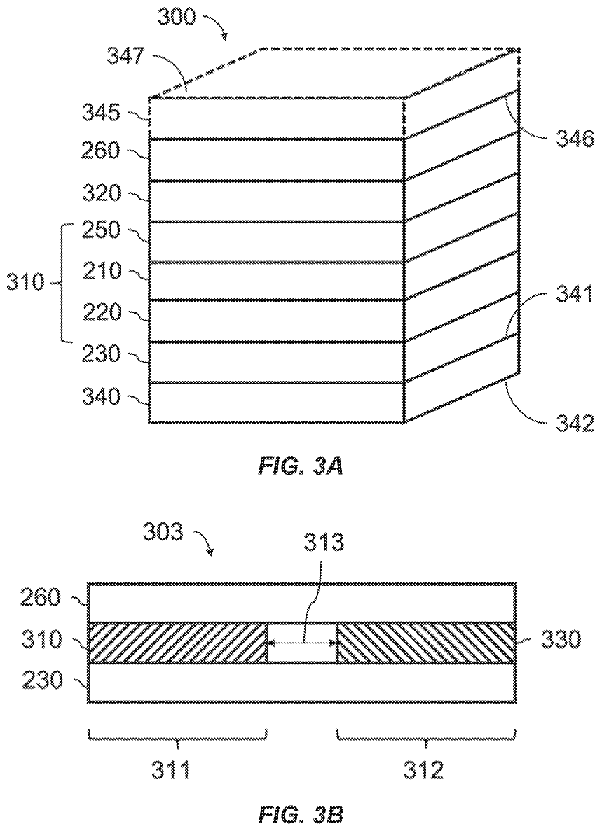

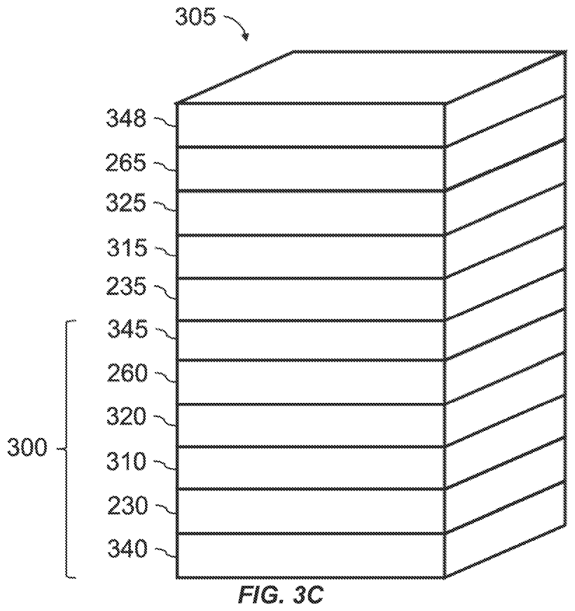

Other devices, such as windows (or films on windows), may have different configurations. For example, referring to FIG. 3A, an embodiment of a window is seen. The window (300) comprises a first substrate (340) with an inner surface (342) and outer surface (341). The window (300) may optionally contain a second substrate (345) that has an inner surface (346) and outer surface (347). Note that “inner” and “outer” surfaces are used here as arbitrary directions referring to two opposite-facing surfaces, where, if the window was positioned in a room, one surface would face in, towards the room, and the other surface would face outward, away from the room.

The first substrate (340) preferably comprises or consists of a glass substrate (e.g., borosilicate glass, alkali-aluminosilicate glass, etc.), although other substrates may be appropriate. Preferably, the second substrate comprises or consists of a glass substrate. The second substrate (345) may be the same or different from the first substrate (340).

The window (300) will generally comprise multiple layers. Depending on the exact configuration of the window, the first substrate (340) may have a film on the inner surface (342), the outer surface (341), or both.

The film will generally comprise a transparent electrode (230) as described previously. Preferably, the transparent electrode is directly in contact with the first substrate.

The film will generally also comprise an electron transport layer (220) in electrical communication with, and preferably in direct contact with, the transparent electrode (230), a disclosed visibly transparent photo-absorbing layer (210) in contact with the electron transport layer (220), and a hole transport layer (250) in contact with the visibly transparent photo-absorbing layer (210). These layers are described previously. These three layers—the electron transport layer (220), visibly transparent photo-absorbing layer (210), and hole transport layer (250)—can be considered as forming a photovoltaic composite layer (310).

The film will also include a second electrode (260), preferably a second transparent electrode. The second electrode is in electrical communication with the hole transport layer.

The film will also include one or more electrochromic thin films (320) in electrical communication with the hole transport layer (250). The electrochromic thin film(s) may independently be comprised or consist of any appropriate electrochromic thin film, such as WO₃, Nb₂O₅, IrO₂, NiO, or V₂O₅.

In some embodiments, such as the embodiment shown in FIG. 3A, the electrochromic thin film (320) is component in a monolithic structure, the electrochromic thin film being positioned between the photovoltaic composite layer and a second electrode.

An alternate configuration can be seen in FIG. 3B, where the window (303) comprises a first electrode (230) and a second electrode (260), and a patterned photovoltaic composite layer (310) and patterned electrochromic layer (330) sandwiched between the two electrode layers. On at least the first electrode (230), there is generally a first portion (311) which is in contact with the patterned photovoltaic composite layer (310) and a second portion (312) in contact with the patterned electrochromic layer (330). Preferably, there is at least some space (313) between the patterns.

The electrochromic layer (330) will comprise or consist of at least one electrochromic thin film. However, as is known by those of skill in the art, additional layers may be included, such as an electrolyte layer sandwiched between the electrochromic thin film and an ion storage layer. The electrolyte layer may be comprised of or consist of any appropriate electrolyte layer material, such as LiAlF₄. The ion storage layer may be comprised of or consist of any appropriate ion storage layer material, such as LiₓV₂O₅.

Another alternate configuration can be seen in FIG. 3C, where the window (305) comprises multiple layers of substrates, photovoltaic composite layers, and electrochromic thin films. Here, a second set of layers are applied onto the window (300) described previously with respect to FIG. 3A.

In particular, on the outer surface of the second substrate (345), a third electrode (235) is shown. This electrode is analogous to the first electrode (230) discussed previously. In some embodiments, the third electrode is the same as the first electrode. In some embodiments, the third electrode is different from the first electrode.

A second photovoltaic composite layer (315) is in electrical communication with, and preferably in direct contact with, the third electrode (235). In some embodiments, the first photovoltaic composite layer (310) is the same as the second photovoltaic composite layer (315). In some embodiments, the first photovoltaic composite layer (310) is the different from the second photovoltaic composite layer (315). For example, it may be of benefit to have different photovoltaic composite layers optimized for different ultraviolet light conditions, which as is known in the art, will be impacted by various factors. Such factors include, but are not limited to, altitude (e.g., an airplane pilot's window while taxiing on a runway will experience a different UV light profile than when the plane is flying at 36,000 feet, and the windows of a building in New York, NY (roughly 50-60 meters above sea level) will experience different UV conditions from a building in La Rinconda, Peru (roughly 5,100 meters above sea level)), or weather conditions (e.g., cloud cover will impact the UVA/UVB ratio of light reaching the windows of an office building or home).

A second electrochromic thin layer (325) may be present that is electrical communication with the hole transport layer of the second photovoltaic composite layer. The second electrochromic thin layer may be the same, or different, as the first electrochromic thin layer (320). In some embodiments, the electrochromic portion of the windows also comprises other layers, such as electrolytes and

A fourth electrode (265) is shown, in electrical communication with, and preferably in direct contact with, the second electrochromic thin layer (325). This electrode is analogous to the second electrode (260) discussed previously. In some embodiments, the fourth electrode is the same as the second electrode. In some embodiments, the fourth electrode is different from the second electrode.

A third substrate (348) is also present, preferably in contact with the fourth electrode. The third substrate preferably comprises or consists of a glass substrate. This substrate is analogous to the first substrate (340) and second substrate (345) discussed previously. In some embodiments, the third substrate is the same as the first substrate, the second substrate, or both. In some embodiments, the third substrate is different from the both the first and second substrate.

Moreover, the transparent perovskite-based device can also be used as one of the cells, in tandem solar cells to improve the power conversion efficiency and stability. Tandem solar cells can typically be considered as comprising at least one cell with a wide bandgap absorber, and at least one cell with a low bandgap absorber. As used here, “wide” and “low” are relative terms. In some embodiments, wide bandgap absorbers have bandgaps of at least 1.5 eV, and low bandgap absorbers have bandgaps of less than 1.5 eV.

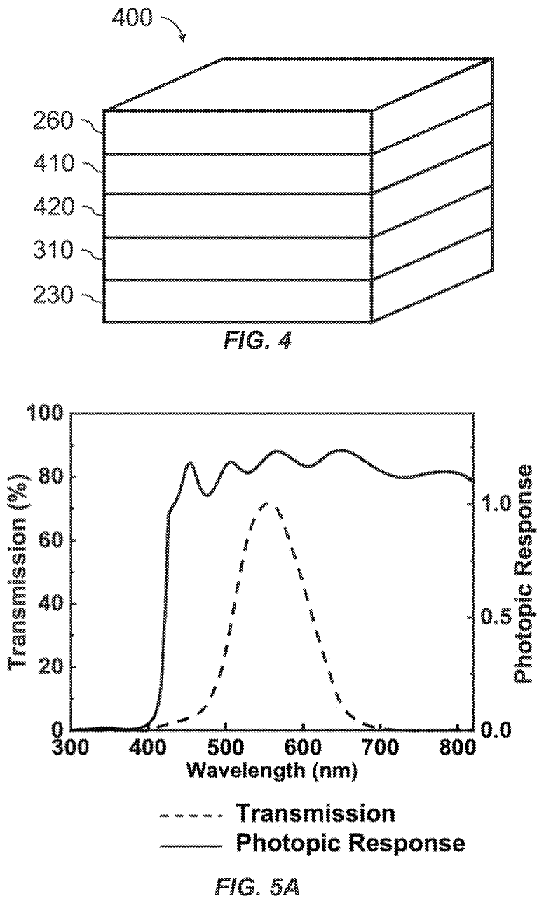

As seen in FIG. 4, a tandem solar cell (400) may comprise, consist essentially of, or consist of a first electrode (230), a second electrode (260), and two photovoltaic composite layers. Preferably, one of the first electrode or second electrode is a metal electrode, and the other is a transparent electrode.

A first composite layer, the photovoltaic composite layer (310) as discussed previously, comprising a disclosed visibly transparent photo-absorbing layer sandwiched between a hole transport layer and an electron transport layer, is in electrical communication with, and preferably in direct contact with, the first electrode (230).

A second composite layer (410), comprising a second light-absorbing layer, is also present in the solar cell. The second composite layer (410) is in electrical communication with, and preferably in direct contact with, the second electrode (260). The second composite layer is also in electrical communication with the first composite layer. In some embodiments, both the first and second composite layers comprise a perovskite layer.

In some embodiments, an intermediate layer (420) is present between the first composite layer (photovoltaic composite layer (310)) and the second composite layer (410). In some embodiments, the intermediate layer (420) is a transparent electrode, which may the same or different from the first electrode, the second electrode, or both. In some embodiments, the intermediate layer (420) comprises Ag, MoOₓ, and ITO.

It is recognized that the toxic Pb in perovskite materials can be overcome by employing encapsulation and on-device lead-sequestration coatings. Thus, in some embodiments, the devices or films are fully or partially encapsulated by, e.g., glass or a transparent polymer.

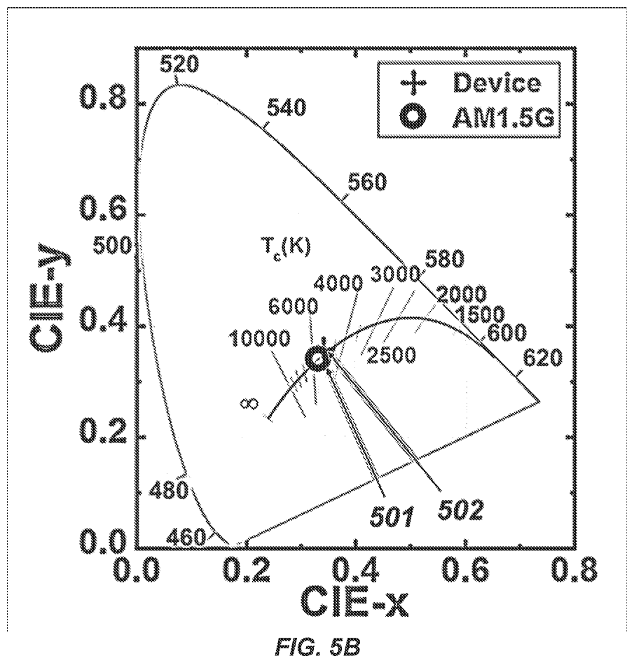

These devices enjoy improved performance characteristics. For example, referring to FIG. 5A, the aesthetic performance of an embodiment of a transparent solar cell can be seen. Specifically, one example device was configured to have the following structure: Glass/ITO/SnO₂/Perovskite (CsPbCl_{2.5}Br_{0.5})/Spiro/ITO shows, for the entire device, a peak transmission of ˜80% at approximately 560 nm. As is seen, the photopic response exceeds a value of 1 at wavelengths above ˜430 nm (that is, across the majority of the visible light region). Further, viewing the color coordinates on the CIE 1931 chromaticity diagram (see FIG. 5B), the coordinates for the device (502) are nearly identical to the coordinates of the global standard spectrum, AM1.5g (501).

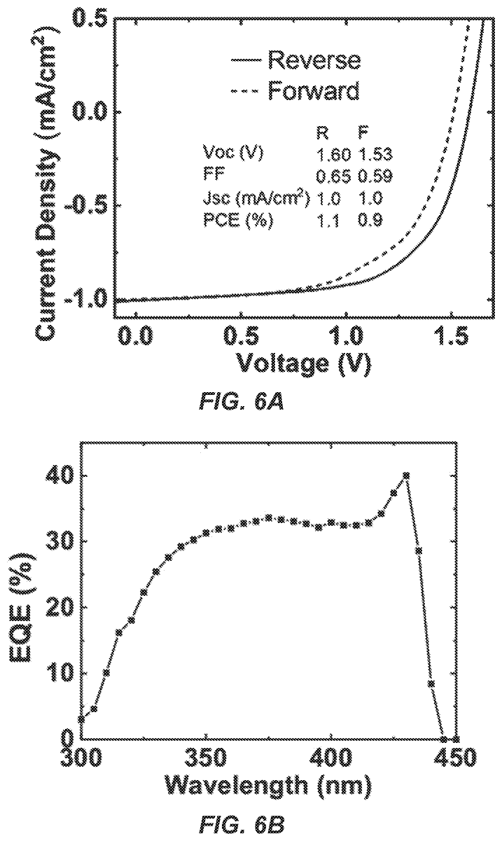

Looking at the photovoltaic performance of the example transparent solar cell, FIG. 6A shows a current density-voltage characteristic of the solar cells. Within such cells, reverse may have a V_{OC} of, e.g., 1.60 V, FF of 0.65, J_{SC} (mA/cm²) of 1.0, and a PCE of 1.1%, while forward may have a V_{OC} of, e.g., 1.53 V, FF of 0.59, J_{SC} (mA/cm²) of 1.0, and a PCE of 0.9%.

FIG. 6B shows the external quantum efficiency (EQE) of an embodiment of the example transparent solar cell.

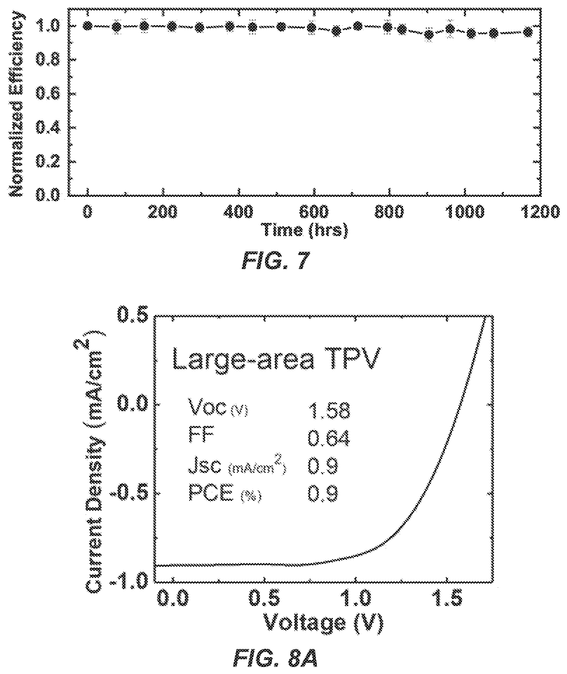

FIG. 7 shows a graph of the stability of the example transparent solar cell. Specifically, it shows the normalized power-conversion efficiency (PCE) for an encapsulated CsPbCl_{2.5}Br_{0.5} solar cell operating at a maximum power point (MPP) under continuous simulated one-sun illumination at ambient conditions (about 40° C., 40% R.H.), tested according to ISOS-L-1I protocol. As is seen, even at 1200 hours of continuous operation, the efficiency remains above 95%.

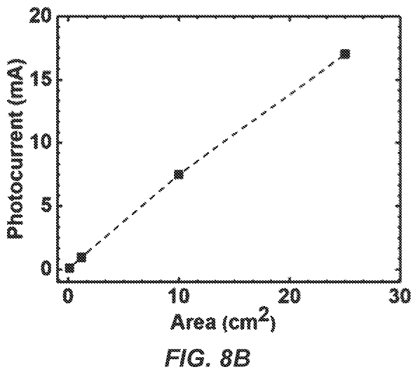

FIG. 8A shows the J-V characteristics of a 1.2 cm² area transparent device having the following structure: Glass/ITO/SnO₂/Perovskite (CsPbCl_{2.5}Br_{0.5})/Spiro/ITO. In particular, this shows a device with a V_{OC} of 1.58 V, a FF of 0.64, a J_{SC} of 0.9 mA/cm², and a PCE of 0.9%. FIG. 8B showing a near-linear correlation between the photocurrent and area of various transparent devices, with devices having areas between 0.9 cm² and 25 cm².

These visibly transparent photo-absorbing layers are preferably manufactured in a particular manner. Specifically, a target substrate is first provided. The target substrate may be, e.g., an electron transport layer or a hole transport layer. A layer is formed on top of the target substrate via thermal co-evaporation, the layer comprising a three-dimensional halide perovskite, double perovskites, ordered-vacancy double perovskites, two-dimensional perovskites, or a combination thereof the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof, X is F, Cl, Br, I, or a combination thereof. The double perovskite preferably has the formula A₂BCX₆, where A is Cs, methylammonium (MA), formamidinium (FA), or combination thereof, B is Cu, Ag, Hg, Au, or a combination thereof, C is Sb, Bi, or a combination thereof, and X is F, Cl, Br, I, or a combination thereof. The two-dimensional perovskite preferably has the formula A₂Bₙ₋₁MₙX₃ₙ₊₁, where A is Cs, RNH₃ (R is an organic group) or a combination thereof, B is R′NH₃ (R′ is an organic group); M is Pb, Sn, Ge, Bi, Sb, Cu, Au, Ag or a combination thereof, X is F, Cl, Br, I, or a combination thereof n denotes that number of M-X sheets in each inorganic layer. The organic groups, R and R′, in embodiments where A is RNH₃ or R′NH₃, may be any organic group, including an alkyl, alkenyl, alkynyl, or aryl groups. R and R′ are preferably different organic groups. In some embodiments, the organic group is a hydrocarbon, having between 1 and 10 carbons. For example, in some embodiments, R and R′ are independently C₆H₅(CH₂)₂ and CH₃. The layer has an absorption cutoff ≤470 nm and a crystallite size >10 nm.

The materials used for thermal co-evaporation and/or sequential evaporation can be any appropriate precursors. As discussed above, the precursors will typically comprise a plurality of halides, including at least one metal halide. In some embodiments, at least one organic halide is utilized as a precursor. In some embodiments, all of the precursors, independently, have compositions according to RXₙ, where X is F, Cl, Br, or I, n is 1-3 (depending on the valence of R), where R can be Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, ANH₃ (A is an organic group), Ag, Au, Ba, Bi, Ca, Co, Cu, Er, Eu, Fe, Ga, Ge, Ho, Hg, In, La, Mg, Mn, Ni, Pb, Sb, Sm, Sn, Sr, Tb, Ti, Y, Yb, or Zn. In some embodiments, the precursors comprise or consist of CsCl, CsBr, and PbCl₂. The organic group, A, in ANH₃ precursors, may be any organic group, including an alkyl, alkenyl, alkynyl, or aryl groups. In some embodiments, the organic group is a hydrocarbon, having between 1 and 10 carbons. For example, in some embodiments, A is CH₃. In a preferred embodiment, A is C₆H₅(CH₂)₂.

The number and composition of the precursors, as well as the molar ratios of the precursors, are generally selected in order to achieve a desired perovskite composition.

These precursors may be provided in any stoichiometrically appropriate molar ratio. In some embodiments, the molar ratio of the precursors (such as PbCl₂:CsCl:CsBr) is equal to 1:0.5:0.5. As examples of molar ratios in other embodiments, for CsPbClₓBr₍₃₋ₓ₎ (0≤x<2), the molar ratio of PbCl₂:PbBr₂:CsBr is preferably (x/2):(1−x/2): 1. For CsPbClₓBr₍₃₋ₓ₎ (2≤x≤3), the molar ratio of PbCl₂:CsCl:CsBr is preferably 1:(x−2):(3−x). Specifically, for some films that were made (for example, CsPbCl₃), x=3. The co-evaporated materials include PbCl₂, CsCl, and CsBr with the molar ratio of 1:1:0. For CsPbCl_{2.5}Br_{0.5}, the co-evaporated materials include PbCl₂, CsCl, and CsBr, with the molar ratio of 1:0.5:0.5.

By fine-tuning the Cl and Br compositions in the perovskite, these visibly transparent photo-absorbing layers can be fabricated with high transmittance and high color rending index. For example, a device that incorporates CsPbClₓBr₍₃₋ₓ₎ as the active layer harvests UV and near-UV photons for power generation, avoiding the competition for visible or infrared photons. Its high conductivity and absorbance enable it to be functional in solar cells with thickness beyond 400 nm, ensuring the high yield rate and high quantum efficiency. In addition, the inorganic material is expected to be more stable than organic materials.

The disclosed approach is not limited to CsPbClₓBr₍₃₋ₓ₎; rather, it is appropriate for many other similar three-dimensional perovskites including MAPbClₓBr₍₃₋ₓ₎, FAPbClₓBr₍₃₋ₓ₎, CsₐMA_{b}FA_{c}PbClₓBr₍₃₋ₓ₎ (a+b+c=1).

CsPbCl₃ and CsPbCl_{2.5}Br_{0.5} films were fabricated by vacuum deposition. The high transmission and high color rendering index of these materials was demonstrated and perovskite solar cells were made which incorporate the CsPbCl_{2.5}Br_{0.5} perovskite film as their active layer. The absorbance of CsPbCl_{2.5}Br_{0.5} and CsPbCl₃ films and the transmittance of CsPbCl_{2.5}Br_{0.5} based solar cells with ITO top electrode was measured, and the performance of perovskite solar cells with ITO as the electrode was characterized. See Figures for more details.

### Example 1 (Three-Dimensional Perovskites)

Perovskite layers were deposited by thermally co-evaporating CsCl, CsBr, and PbCl₂ from different sources in vacuum (<3×10⁻⁶ mbar) with a total evaporation rate of 5 Å/s. The molar ratio of CsCl, CsBr, and PbCl₂ is adjusted from 1:0:1, 1:1:2 to 0:1:1 for CsPbCl₃, CsPbCl_{2.5}Br_{0.5} and CsPbCl₂Br perovskite films, respectively. During co-evaporation, the evaporation rate of each source is monitored by one quartz crystal microbalance sensor. In this example, the co-evaporation took about 10 min until the perovskite layer had a thickness of approximately 400 nm. After co-evaporation, the samples are then transferred to a nitrogen glovebox and annealed at 150° C. for 10 min.

### Example 2 (Double Perovskites)

Perovskite layers were deposited by thermally co-evaporating CsCl, CsBr, AgCl₂, AgBr₂, BiCl₃, and BiBr₃ from different sources in vacuum (<3×10⁻⁶ mbar) with a total evaporation rate of 5 Å/s. The molar ratio of CsCl, CsBr, AgCl₂, AgBr₂, BiCl₃, and BiBr₃ is adjusted to x:(1−x):y:(1−y):z:(1−z) for Cs₂AgBiCl_{x+2y+3z}Br_{6-x-2y-3z} perovskite films, where 0≤x≤1, 0≤y≤1, 0≤z≤1. During co-evaporation, the evaporation rate of each source is monitored by one quartz crystal microbalance sensor. In this example, the co-evaporation took about 10 min until the perovskite layer had a thickness of approximately 400 nm. After co-evaporation, the samples are then transferred to a nitrogen glovebox and annealed at 200° C. for 10 min.

### Example 3 (Two-Dimensional Perovskites)

Perovskite layers were deposited by thermally co-evaporating C₈H₁₂ClN (PEACl, phenylethylamine hydrochloride), C₈H₁₂BrN (PEABr, phenylethylamine hydrobromide), PbCl₂ and PbBr₂ from different sources in vacuum (<3×10⁻⁶ mbar) with a total evaporation rate of 5 Å/s. The molar ratio of PEACl, PEABr, PbCl₂ and PbBr₂ is adjusted to 2x:(2−2x):y:(1−y) for PEA₂PbCl_{2x+2y}Br_{4-2x-2y} perovskite films, where 0≤x≤1 and 0≤y≤1. During co-evaporation, the evaporation rate of each source is monitored by one quartz crystal microbalance sensor. In this example, the co-evaporation took about 10 min until the perovskite layer had a thickness of approximately 400 nm. After co-evaporation, the samples are then transferred to a nitrogen glovebox and annealed at 100° C. for 10 min.

An important advantage is that the disclosed perovskite solar cells have higher transmittance, higher efficiency and higher yield rate, lower cost, and higher stability compared to other transparent solar cells. In addition, its fabrication method is easier and more environmentally friendly than a solution process.

Those skilled in the art will recognize or be able to ascertain using no more than routine experimentation many equivalents to the specific embodiments of the invention described herein. Such equivalents are intended to be encompassed by the following claims.

What is claimed is:

1. A visibly transparent photo-absorbing layer, comprising:
a three-dimensional halide perovskite having a formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof, X is F, Cl, Br, I, or a combination thereof;
a double perovskite having a formula A₂BCX₆, where A is Cs, methylammonium (MA), formamidinium (FA), or combination thereof, B is Cu, Ag, Hg, Au, or a combination thereof, C is Sb, Bi, or a combination thereof, and X is F, Cl, Br, I, or a combination thereof;
a two-dimensional perovskite having a formula A₂Bₙ₋₁MₙX₃ₙ₊₁, where A is Cs, RNH₃ (where R is an organic group), or a combination thereof; B is R′NH₃ (where R′ is an organic group); M is Pb, Sn, Ge, Bi, Sb, Cu, Au, Ag or a combination thereof, X is F, Cl, Br, I, or a combination thereof, n denotes that number of M-X sheets in each inorganic layer, and n is at least 2; or
a combination thereof,
wherein the visibly transparent photo-absorbing layer has an absorption cutoff ≤470 nm; and
wherein the visibly transparent photo-absorbing layer has a crystallite size >10 nm.

2. The visibly transparent photo-absorbing layer according to claim 1, wherein the three-dimensional halide perovskite, the double perovskite, the two-dimensional perovskite, or the combination thereof comprises an inorganic, organic, or hybrid perovskite having the formula:
CsₐMA_{b}FA_{c}Pb_{d}Ge_{c}Sn_{f}FₓCl_{y}Br_{z}, where a+b+c=1, d+e+f=1, x+y+z=3, 0≤a, b, c, d, e, f≤1, 0≤x, y, z≤3;
Cs₂AgBiCl_{x+2y+3z}Br_{6-x-2y-3z}, where 0≤x≤1, 0≤y≤1, 0≤z≤1;
PEA₂PbₐSn₁₋ₐCl_{2x+2y}Br_{4-2x-2y}, where 0≤a≤1, 0≤x≤1 and 0≤y≤1; or
Cs₂PbₓSn_{y}I₂Cl₂, where x+y=1, 0≤x≤1 and 0≤y≤1.

3. A visibly transparent photo-absorbing layer according to claim 1, wherein the visibly transparent photo-absorbing layer is formed by via thermal co-evaporation, sequential thermal evaporation or a combination thereof of, using precursors that independently have compositions according to RXₙ, where X is F, Cl, Br, or I, n is 1-3 (depending on the valence of R), where R can be methylammonium (MA), formamidinium (FA), ethanediammonium, iso-propylammonium, dimethylammonium, guanidinium, piperidinium, pyridinium, pyrrolidinium, imidazolium, t-butylammonium, ANH₃ (where A is an organic group) or a metal.

4. A perovskite solar cell, comprising:
a visibly transparent substrate comprising glass, a rigid polymer, or a flexible polymer; and
a transparent electrode deposited above the visibly transparent substrate;
a photovoltaic composite layer above the transparent electrode, the photovoltaic composite layer comprising a visibly transparent photo-absorbing layer between an electron transport layer and a hole transport layer; and
a second electrode above the photovoltaic composite layer;
wherein the photo-absorbing layer is a three-dimensional halide perovskite, a double perovskite, a two-dimensional perovskite, or a combination thereof;
wherein the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof, and wherein the double perovskite has the formula A₂BCX₆, where A is Cs, methylammonium (MA), formamidinium (FA), or combination thereof; B is Cu, Ag, Hg, Au, or a combination thereof; C is Sb, Bi, or a combination thereof; and X is F, Cl, Br, I, or a combination thereof;
wherein the double perovskite has the formula A₂BCX₆, where A is Cs, methylammonium (MA), formamidinium (FA), or combination thereof, B is Cu, Ag, Hg, Au, or a combination thereof; C is Sb, Bi, or a combination thereof; and X is F, Cl, Br, I, or a combination thereof;
wherein the two-dimensional (2D) perovskite has the formula A₂Bₙ₋₁MₙX₃ₙ₊₁, where A is Cs, RNH₃ (where R is an organic group) or a combination thereof; B is R′NH₃ (where R′ is an organic group); M is Pb, Sn, Ge, Bi, Sb, Cu, Au, Ag or a combination thereof, X is F, Cl, Br, I, or a combination thereof, n denotes that number of M-X sheets in each inorganic layer, and n is at least 2;
wherein the visibly transparent photo-absorbing layer has an absorption cutoff ≤470 nm; and
wherein the visibly transparent photo-absorbing layer has a crystallite size >10 nm.

5. The perovskite solar cell according to claim 4, wherein the transparent electrode is indium tin oxide (ITO), fluorine doped tin oxide (FTO), indium zinc oxide, InZnAlO, ZnAlO, a conductive nanotube, a conductive nanoparticle, cadmium oxide, zirconium indium oxide, gallium zinc oxide, graphene, graphene oxide, graphite, carbon nanotube, carbon, Ag, Al, Au, Mo, Cu, Ni, Ca, Li, poly(3,4-ethylenedioxythiophene) polystyrene sulfonate (PEDOT:PSS) or a combination thereof.

6. The perovskite solar cell according to claim 4, wherein the electron transport layer comprises TiO₂, SnO₂, ZnO, ZnSnO₄, Cs₂CO₃, BaTiO₃, SrTiO₃, MgTiO₃, BaSnO₃, CdS, ZnTiO₃, WO₃, a conductive nanotube, a conductive nanoparticle, fullerene and its derivatives, self-assembled monolayers, MXene (2D transition metal carbides and nitrides with a composition of Mₙ₊₁XₙTₓ), indium gallium zinc oxide (InGaZnO₄), gallium nitride (GaN), niobium pentoxide (Nb₂O₅), In₂S₃, SnS₂, Bi₂S₃, MoS₂, WS₂, reduced graphene oxide, perylene diimide and its derivatives, naphthalene diimide and its derivatives, azaacene and its derivatives, n-type conjugated polymers, bathocuproine, bathophenanthroline, 2,2′,2″-(1,3,5-Benzinetriyl)-tris(1-phenyl-1-H-benzimidazole) (TPBi), tris[2,4,6-trimethyl-3-(pyridine-3-yl)phenyl]borane (3TPYMB), 3,3′,5,5′-tetra[(m-pyridyl)-phen-3-yl]biphenyl (BP4mPy), Tris(8-hydroxyquinoline)aluminum(III) (Alq₃), N,N′-Bis(naphthalen-1-yl)-N,N′-bis(phenyl)benzidine (NPD), 4,4′-Bis(N-carbazolyl)-1,1′-biphenyl (CBP), N,N′-Bis(3-methylphenyl)-N,N′-diphenylbenzidine (TPD), Tris(4-carbazoyl-9-ylphenyl)amine (TCTA), 1,1-Bis[(di-4-tolylamino)phenyl]cyclohexane (TAPC), 1,3,5-Tris(3-pyridyl-3-phenyl)benzene (TmPyPB), Hexaazatriphenylenehexacarbonitrile (HATCN), a derivative thereof, or a doped layer thereof, or a combination thereof.

7. The perovskite solar cell according to claim 4, wherein the hole transport layer comprises 2,2′,7,7′-tetrakis(N,N-di-p-methoxyphenyl-amine)-9,9′-spirobifluorene (spiro-OMeTAD), Pedot:PSS, Poly(3-hexylthiophene-2,5-diyl) (P3HT), Poly(triaryl amine) (PTAA), NiOₓ, CuSCN, Cu₂O, CuOₓ, CuO, MoOₓ, NiPc, CuPc, VOₓ, V₂Oₓ, Cr, CrOₓ, Co₃O₄, CoOₓ, Co_{1-y}Cu_{y}Oₓ, reduced graphene oxide, Alq₃, NPD, CBP, TPD, TCTA, TAPC, BP4mPy, TmPyPB, HATCN, Poly [(9,9-bis(3′-(N,N-dimethylamino)propyl)-2,7-fluorene)-alt-2,7-(9,9-dioctylfluorene)] (PFN), self-assembled monolayers, a conductive nanoparticle, a conductive nanotube, p-type conjugated polymers, a derivative thereof, or a doped layer thereof, or a combination thereof.

8. The perovskite solar cell according to claim 4, wherein the visibly transparent photo-absorbing layer is formed by via thermal co-evaporation, sequential thermal evaporation or a combination thereof of, using precursors that independently have compositions according to RXₙ, where X is F, Cl, Br, or I, n is 1-3 (depending on the valence of R), where R can be methylammonium (MA), formamidinium (FA), ethanediammonium, iso-propylammonium, dimethylammonium, guanidinium, piperidinium, pyridinium, pyrrolidinium, imidazolium, t-butylammonium, ANH₃ (where A is an organic group) or a metal.

9. A window, comprising:
a substrate having an inner surface and an outer surface; and
at least one film in contact with the inner surface, the outer surface, or both, each film comprising a visibly transparent photo-absorbing layer according to claim 1.

10. The window according to claim 9, wherein the film comprises:
a transparent electrode;
an electron or hole transport layer in electrical communication with the transparent electrode;
the visibly transparent photo-absorbing layer in contact with the electron transport layer;
a hole or electron transport layer in contact with the visibly transparent photo-absorbing layer;
a second electrode in electrical communication with the hole or electron transport layer; and
one or more electrochromic thin films in electrical communication with the hole transport layer.

11. A method for manufacturing a visibly transparent photo-absorbing layer, comprising:
providing a target substrate, the target substrate comprising glass, a rigid polymer, a flexible polymer, an electron transport layer or a hole transport layer; and
forming at least one perovskite layer via thermal co-evaporation, sequential thermal evaporation or a combination thereof, the at least one perovskite layer comprising a three-dimensional halide perovskite, a double perovskite, a two-dimensional perovskite, or a combination thereof,
wherein the three-dimensional halide perovskite has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof, B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof,
wherein the double perovskite has the formula A₂BCX₆, where A is Cs, methylammonium (MA), formamidinium (FA), or combination thereof, B is Cu, Ag, Hg, Au, or a combination thereof; C is Sb, Bi, or a combination thereof; and X is F, Cl, Br, I, or a combination thereof;
wherein the two-dimensional perovskite has the formula A₂Bₙ₋₁MₙX₃ₙ₊₁, where A is Cs, RNH₃ (R is an organic group) or a combination thereof; B is R′NH₃ (R′ is an organic group); M is Pb, Sn, Ge, Bi, Sb, Cu, Au, Ag or a combination thereof, X is F, Cl, Br, I, or a combination thereof, n denotes that number of M-X sheets in each inorganic layer, and n is at least 2;
wherein the layer has an absorption cutoff ≤470 nm; and
wherein the layer has a crystallite size >10 nm.

12. The method according to claim 11, wherein a plurality of two-dimensional perovskites are formed, each in contact with at least one other two-dimensional perovskite, each independently having the formula A₂Bₙ₋₁MₙX₃ₙ₊₁, where A is Cs, RNH₃ (R is an organic group) or a combination thereof, B is R′NH₃ (R′ is an organic group); M is Pb, Sn, Ge, Bi, Sb, Cu, Au, Ag or a combination thereof, X is F, Cl, Br, I, or a combination thereof, n denotes that number of M-X sheets in each inorganic layer, and n is at least 2, wherein each of the plurality of two-dimensional perovskites varies in n.

13. The method according to claim 11, wherein the formed at least one perovskite layer comprises a three-dimensional halide perovskite or a two-dimensional perovskite, and wherein the method further comprises forming an additional perovskite layer via thermal co-evaporation, sequential thermal evaporation, or a combination thereof over the at least one perovskite layer, the additional perovskite layer comprising the other of the three-dimensional halide perovskite or two-dimensional perovskite.

14. The method according to claim 11, wherein the visibly transparent photo-absorbing layer is formed with precursors that independently have compositions according to RXₙ, where X is F, Cl, Br, or I, n is 1-3 (depending on the valence of R), where R can be Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, ANH₃ (where A is an organic group), or a metal.

15. The method according to claim 11, further comprising selecting a number of precursors, selecting a composition of each precursor, and determining the molar ratio of the precursors to achieve a desired perovskite composition.
